(19) United States
(12) Patent Application Publication
(10) Pub. No.: US 2022/0045236 A1
(43) Pub. Date: Feb. 10, 2022

(54) MICRO LED LASER RELEASE FROM SILICON WAFER

(71) Applicants: Paul West, Portland, OR (US); Khaled Ahmed, San Jose, CA (US)

(72) Inventors: Paul West, Portland, OR (US); Khaled Ahmed, San Jose, CA (US)

(21) Appl. No.: 17/485,398

(22) Filed: Sep. 25, 2021

(51) Int. Cl. H01L 33/00; H01L 33/60

(52) U.S. Cl. CPC H01L 33/0093; H01L 33/24; H01L 33/60; H01L 33/007

(57) ABSTRACT

Methods and systems for improving the yield of laser ablation of semiconductor devices, such as micro-LEDs, in a direct transfer method are described. In the disclosed embodiments, an ablation layer is used to mask a nucleation layer on a donor substrate, with an aperture provided to allow epitaxial growth of a semiconductor structure. The aperture size is selected as the minimum necessary to ensure proper epitaxial growth. Layers disposed above the ablation layer may have larger apertures to that a portion of the semiconductor structure stem overlies the ablation layer, allowing a greater force generated during the ablation process to be directed against the semiconductor structure, improving the likelihood of separation of the structure from the donor substrate. Other embodiments are described.

### TECHNICAL FIELD

Disclosed embodiments are directed to techniques for manufacturing micro LEDs, and in particular to techniques for improving the yield of micro LEDs when using a direct transfer method.

### BACKGROUND

Electronic display panels, such as may be found in a computer monitor or flat-panel television, may be implemented using a number of different technologies. Some such technologies include plasma, liquid-crystal display (LCD), light-emitting diode (LED), organic light-emitting diode (OLED), and laser projection, to name just a few. Panels utilizing LED technologies are increasingly popular, as LEDs offer a reliable, cool, and energy-efficient means of producing light. LED technologies may be used in display panels in different functions. For example, some LCD displays may use white LEDs as a backlight source. However, conventional LCD displays suffer from a number of limitations, including limitations on contrast and increasing image distortion or shift as the panel is viewed increasingly off-axis. While the use of LED backlights allows some of these limitations to be largely removed, as in the case of turning off backlight sections where a picture is black to improve contrast, these limitations still typically exist to some extent.

Until recently, the use of LEDs has been limited to backlights. However, as micro LEDs become available in sizes that are sufficiently small to act as individual pixels, displays may utilize such micro LEDs to directly produce an image, rather than as a backlight for a filter, providing a number of advantages over existing LCD panels (even when such panels are LED backlit), such as improved viewing angles, contrast, latency, and color saturation. For example, white micro LEDs can be used to create a monochrome display panel. Increasingly, micro LEDs are available in pixel sizes that can produce light in the specific wavelengths needed to reproduce a color picture, e.g. red, green, and blue, allowing a flat panel color display to be created directly from the micro LEDs, with red, green, and blue micro LEDs forming sub-pixels for each display pixel.

In addition to display technologies, micro LEDs may have other uses, such as chip-to-chip or intra-chip optical interconnection. The microscopic size of the LEDs allows such structures to be closely integrated into microchip packaging.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 depicts the arrangement of layers for growing a micro-LED that is released by ablation, as known in the prior art.

FIG. 2A depicts an example arrangement of layers for growing a micro-LED that allows for increased release force from ablation, according to various embodiments.

FIG. 2B depicts the arrangement of layers of FIG. 2A with a micro-LED having been grown, illustrating the example arrangement as it relates to the micro-LED, according to various embodiments.

FIG. 3 depicts the arrangement of layers of FIGS. 2A and 2B following attachment of a recipient substrate and ablation of the ablation layer to release the donor substrate, according to various embodiments.

FIG. 4A depicts a first possible embodiment arrangement of the various layers to facilitate laser ablative release of a micro-LED.

FIG. 4B depicts a second possible embodiment arrangement of the various layers to facilitate laser ablative release of a micro-LED.

FIG. 4C depicts a third possible embodiment arrangement of the various layers to facilitate laser ablative release of a micro-LED.

FIG. 5 is a flowchart of the operations of an example method for growing a micro-LED with increased released force from ablation, according to various embodiments.

FIG. 6 is a block diagram of an example computer that can be used to implement some or all of the components of a system that may be used in fabricating a micro-LED or performing some of the operations of the example method of FIG. 5, according to various embodiments.

FIG. 7 is a block diagram of a computer-readable storage medium that can be used to implement some of the components of the methods disclosed herein, according to various embodiments.

### DETAILED DESCRIPTION

Panels that employ micro-LEDs require fabrication techniques that can generate micro-LED structures in sub-pixel sizes. For high pixel density displays, such as may be found on a mobile device, in a virtual reality headset, camera electronic viewfinder, or on ultra-high definition displays, to name a few examples, each micro-LED may need to be sized on the order of a few microns. Likewise, for chip-to-chip interconnects, such as where the interconnects may be integrated for communication between chips in a single package, micron-sized micro-LEDs may be needed. Production of micro-LEDs in the micron size range requires fabrication techniques similar to those used to produce microchips, where such micro-LEDs are fabricated directly onto donor silicon wafers. Such processes may have varying yields, with improving yield percentages important to allow micro-LEDs to be commercially viable.

The main process limiting the yield of micro-LED displays is the Direct Transfer Method (DTM). In the DTM process, micro-LEDs are fabricated on a silicon wafer substrate, then transferred onto a second substrate. The type of second substrate may vary depending upon the target application for the micro-LEDs. Where the micro-LEDs are intended for chip-to-chip optical interconnects, the second substrate may be a second silicon wafer. Where the micro-LEDs are intended for display panels, the second substrate may be a glass backplane. In either case, mass production of the micro-LEDs is desirable to improve the commercial viability of the micro-LED technology. The DTM process is the primary yield-limiting step in micro-LED manufacturing, so improving the yield at this step is crucial for display yield.

The fabrication process involves growing the micro-LED structure on a suitably prepared silicon wafer, then directly transferring the grown micro-LED structure to the second substrate. As noted above, this second substrate may be a second silicon wafer, a glass backplane, another display component, or another suitable receiving substrate, depending upon the end application for the micro-LEDs. Depending on the size of the wafer, multiple micro-LEDs may be grown on a single wafer, similar to how other semiconductor devices may be mass produced, to provide a relatively high yield. Key to this direct transfer process is releasing the micro-LEDs following growing on the wafer and adhering to the second substrate, so that the donor silicon wafer can be released, leaving the micro-LEDs secured to the second substrate.

One possible approach to effecting release is forming an ablation layer, typically from a metal nitride material, on the donor silicon wafer, above which the micro-LED is formed. Following formation of the micro-LED and securing to the second substrate, a suitably-powered laser pulse is directed to the ablation layer, causing it to vaporize and thereby generate a force biasing the micro-LED away from the surface of the donor silicon wafer. This force must be sufficiently strong to cause the micro-LED to detach from the donor silicon wafer, leaving it secured to the second substrate. If the ablation force is insufficient, the micro-LED may not remain secured to the second substrate, and/or the micro-LED structure may break or fracture, rendering the micro-LED useless. Thus, how the micro-LED is grown and the extent to which it is attached to the donor silicon wafer impacts the ease of release.

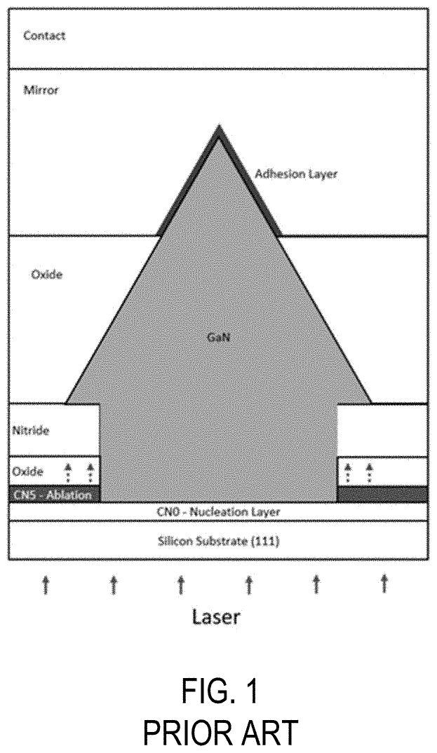

Micro-LEDs may be grown into a number of different physical configurations, which may have varying degrees of suitability to different sized wafers, and may be more or less suited to formation of various layers to achieve a desired LED color. In a typical formation process, a stem of Gallium nitride (GaN) is formed from a nucleation layer and grows vertically through one or more oxide and/or nitride layers before expanding laterally in parallel with the nucleation layer and over the oxide and/or nitride layers. The aforementioned ablation layer is typically disposed between the nucleation layer and the oxide and/or nitride layers. However, the portion of the nucleation layer from which the stem grows is left exposed through the ablation, oxide, and nitride layers, as the GaN must form from the nucleation layer. FIG. 1 illustrates this arrangement of layers, with a micro-LED formed from the nucleation layer.

As can be seen from FIG. 1, the formation process typically results in the metal nitride ablation area surrounding and disposed along the sides of the stem from which the micro-LED forms. Importantly, none of the ablation layer is located beneath the GaN stem, which is adhered to the nucleation layer across its width. When a pulsed laser is directed from the bottom of this structure, ablation occurs in the metal nitride layer—causing an upward force that pushes everything above the nucleation layer upward, forcing its transfer into a receiving wafer. This arrangement poses several problems: 1) There is a strong bond between the nucleation layer and GaN layer, so at least a correspondingly strong releasing force is required for proper separation. 2) The ablation area is along the sides of the stem of the pyramid structure, rather than underneath the structure, so while the removal force is straight up, it is not directly applied to the bulk of the GaN stem, but rather only to the relatively thin edge or lip of GaN that extends over the nitride layer. 3) Because very little of the metal nitride layer is beneath the pyramid (only a small amount below the pyramid edge), very little ablation force is applied to the GaN structure for removal.

Thus, ablation may fail to detach the micro-LED if the force imparted to the edge is insufficient to break the bond between the stem and the nucleation layer, such as due to insufficient ablation material. Alternatively, the edge may have insufficient structural strength to transfer the necessary force to break the bond, resulting in a portion or all of the edge breaking or shearing off while leaving all or substantially all of the stem still attached to the nucleation layer. In either case, the relatively small area available to transfer the ablation force to release the micro-LED requires precise sizing of the ablation layer thickness and GaN edge. This precise sizing may be difficult to consistently achieve, resulting in unacceptably low yields.

Disclosed embodiments address these shortcomings by altering the structure and formation of the various layers so that the portion of the GaN stem of the micro-LED that remains attached to the nucleation layer is decreased, thereby reducing the force needed to effect separation, while at the same time increasing the amount of force from ablation that is transferred to the stem and body of the micro-LED, which can better absorb the force as compared to the GaN edge. Consequently, the need for precise sizing is reduced and tolerance for slight variations in layer thicknesses is increased while still allowing for consistent release, thereby improving yields.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

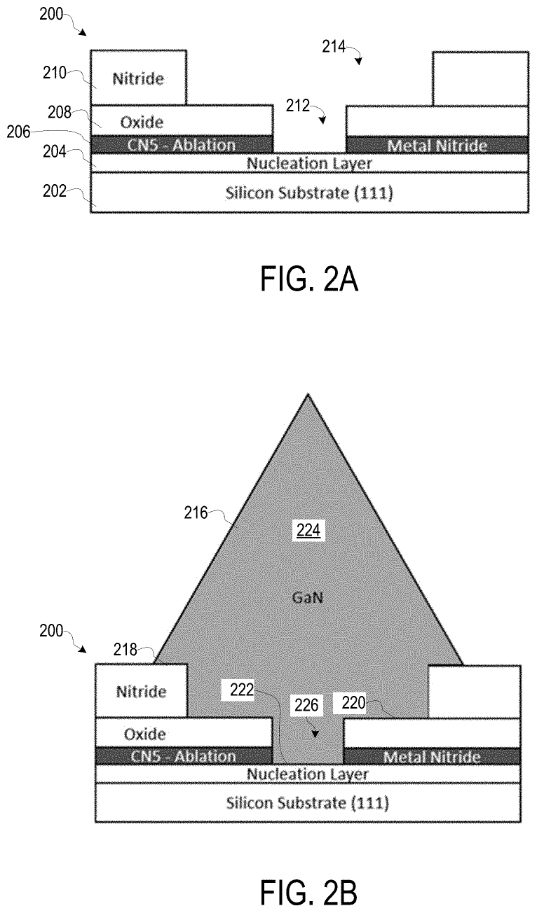

FIGS. 2A and 2B illustrate an example arrangement 200 of layers on a substrate 202 for growing a semiconductor structure 216 such as a micro-light emitting diode (micro-LED), according to some embodiments. Arrangement 200, as depicted in FIG. 2A, includes substrate 202, a nucleation layer 204, an ablation layer 206, an oxide layer 208, and a nitride layer 210.

Substrate 202, in embodiments, is a silicon wafer, which may be of Miller index lattice type 111, that is lightly p-type doped to create micro-LEDs. Other wafers or substrates, which may be differently prepared or doped, may be employed depending upon the type of device that is to be created. Following any necessary preparation of the substrate 202, a uniform continuous nucleation layer 204 is applied or formed to the regions of the substrate 202 where the semiconductor structures 216 are to be grown. In the depicted embodiment, for micro-LEDs, the material of the nucleation layer 204 is selected to allow epitaxial growth of Gallium nitride (GaN) at a later step. In other implementations, the nucleation layer 204 may be made from a different material, such as when a different type of semiconductor structure 216 is being grown. The nucleation layer 204 is also attached to the semiconductor structure 216 as the structure grows from the nucleation layer 204; this attachment must later be broken by ablation to release the semiconductor structure 216 from the substrate 202.

On top of the nucleation layer 204, an ablation layer 206 is formed and patterned with an opening or aperture 212 to the nucleation layer 204 to allow the semiconductor structure 216, here, a GaN crystalline growth, to be formed and grown on the nucleation layer 204. The ablation layer 206 is a sacrificial layer which will be ablated to promote separation of the substrate 202 and nucleation layer 204 from the remaining layers when the semiconductor structure 216 is to be released from the substrate 202 and nucleation layer 204. When the ablation layer 206 is irradiated with a laser, the ablation layer 206 can vaporize as it absorbs energy from the laser and the vaporization gas pressure results in the separation of the semiconductor structure 216 from the nucleation layer 204 and substrate 202. In some embodiments, the laser used for ablation is an infrared laser with a wavelength of approximately 1950 nm, and may be directed to the side of the substrate opposite the side on which the semiconductor structure 216 is formed, viz. the laser light passes through the substrate 202, then the nucleation layer 204, to impact the ablation layer 206. The ablation layer 206 can comprise titanium nitride, niobium nitride, tantalum nitride, another metal nitride, or any other material suitable for use in releasing the semiconductor structure 216 from the substrate 202 and nucleation layer 204 via laser irradiation. In some embodiments, the thickness of the ablation layer 206 can be in the range of about 5-50 nm. In other embodiments, the thickness of the ablation layer 206 can be in the range of about 10-30 nm. In still other embodiments, the ablation layer 206 may be formed from another metal nitride of a suitable type. The material of ablation layer 206 should be selected both to resist formation of and adhesion to the material of the semiconductor structure 216, to ensure that semiconductor structure 216 is properly formed in its intended configuration. In other embodiments, other materials may be used for the ablation layer 206 that are compatible with the other layers of arrangement 200 and the type and/or configuration of the semiconductor structure 216.

Formed on top of the ablation layer 206, one or more fill dielectric layers 208, 210, which may be formed from an oxide (eg. SiO2) and/or nitride (eg. Si3N4), are patterned as a mask for growth of the semiconductor structure 216. These dielectric layers 208 and 210 each also have an aperture 214 that allows both formation and growth of the semiconductor structure 216 as well helping to control and direct the final shape of the semiconductor structure 216. The aperture 214 of dielectric layers 208 and 210 are arranged concentrically or substantially concentrically with the aperture 212 of the ablation layer 206. The size of the apertures 212, 214 of these three layers help promote separation during the ablation process, and will be discussed in more detail later. As with the nucleation layer 204 and ablation layer 206, the composition of the dielectric layers 208 and/or 210 may vary depending upon the selection of materials in the other layers and/or depending upon the type of semiconductor structure 216 that is being grown. Furthermore, although two different dielectric layers 208 and 210, of different materials, are illustrated, it should be understood by a person skilled in the relevant art that other embodiments may employ fewer or greater numbers of dielectric layers, which themselves may be made of different materials. In still other embodiments, dielectric layers 208 and 210 may be omitted altogether, with the bulk of the semiconductor structure 216 being formed atop the ablation layer 206, from nucleation layer 204 via a relatively small aperture 212.

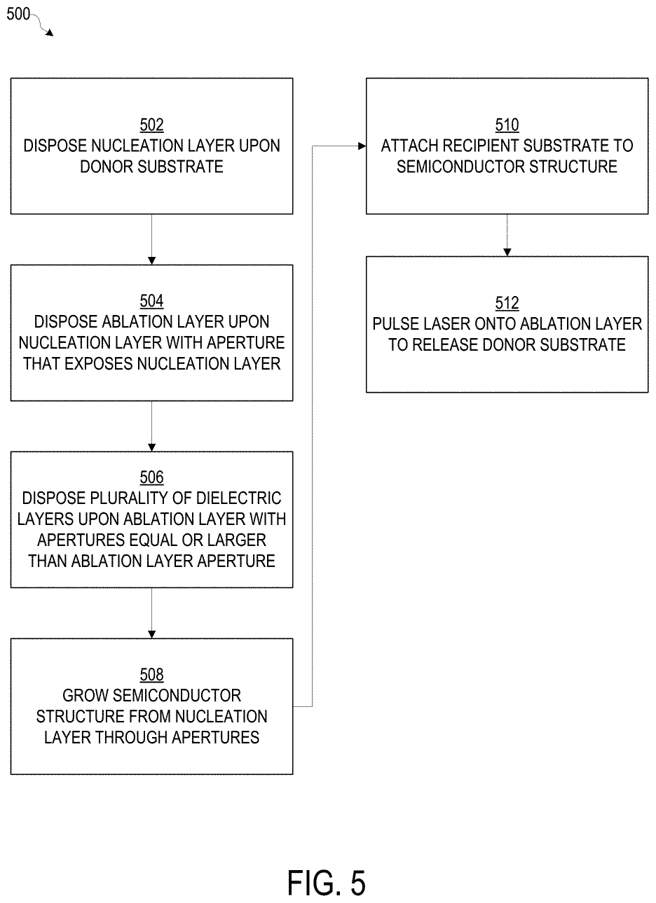

As depicted in FIG. 2B, the semiconductor structure 216 is grown or formed from the nucleation layer 204 at an interface point 222, through apertures 212 and 214, and into a pyramidal structure that overlaps a portion of the top dielectric layer 210 to form an edge or lip 218. The semiconductor structure 216 includes a stem 226, defined as the portion that passes through the apertures 212 and 214, and a body 224, which extends away from the apertures 212 and 214 across the top dielectric layer 210. It should be appreciated that the position of “top” or “topmost” in reference to the dielectric layers is made with reference to the substrate 202 as the “bottom” layer or reference plane, and should not be understood as suggesting any particular orientation of the wafer during processing. In other terms, the topmost layer of the dielectric layers is that layer that is most proximate to the body 224 of the semiconductor structure 216, over which the body 224 extends. As can be seen in FIG. 2B, the body 224 in the example embodiment has a pyramidal or conical shape. In the depicted embodiment where a micro-LED is being fabricated, the semiconductor structure 216, here a GaN epitaxial nanopyramid, is grown to a height of ˜600 nm for blue LEDs and ˜400 nm for green LEDs. Coming out of the lattice-matched nucleation layer 204, the base of the growth will be confined by the ablation layer 206, oxide and nitride dielectric layers 208 and 210. It should be appreciated that, owing to the arrangement of layers and apertures, the pyramid structure of the example semiconductor structure 216 forms a shelf 220 that extends above and across the dielectric oxide/nitride layers 208 and 210. These operations are discussed below with respect to FIG. 5. While the depicted structure is a nanopyramid, other semiconductor structures 216 may be grown to different geometries and structures, depending upon the nature of the intended device, subject to suitability to the ablation process for removal. Semiconductor structure 216 may be grown using any suitable process that is appropriate for the nature of the semiconductor structure, typically providing for epitaxial growth. For example, vapor-phase, liquid-phase, or solid-phase epitaxy processes may be selected depending upon the nature of the semiconductor being fabricated and the size and type of substrate 202. In other examples, molecular beam epitaxy may be utilized, depending upon the size of the substrate 202. The selection of the epitaxy process may further depend upon costs, yields, and the nature of the final product in which the semiconductors are to be used. Still other types of processes may be employed, depending upon the intended application.

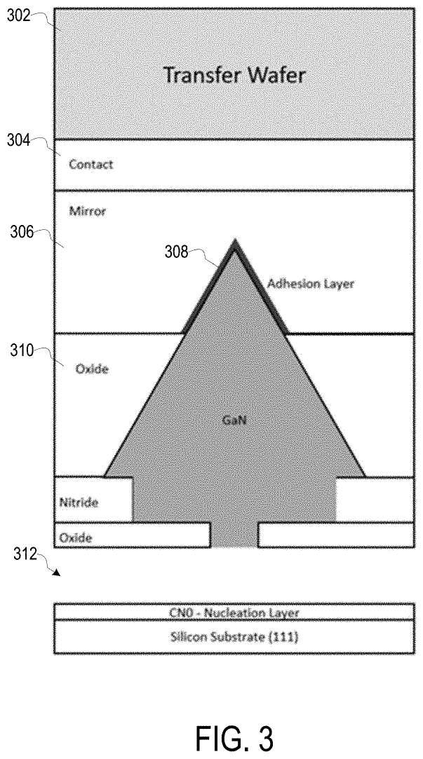

Turning to FIG. 3, the configuration of the example arrangement 200 of layers is depicted following attachment of several different layers, as well as the recipient substrate 302, here a transfer wafer. Prior to attaching to the recipient substrate 302, additional layers may be added to complete the necessary structures to enable the semiconductor structure 216 to function correctly.

In the depicted embodiment, an additional oxide layer 310, which may be of an identical material to dielectric layer 208 or another suitable oxide, may be deposited to surround the semiconductor structure 216. Processing continues using traditional processes, including the addition of an adhesion layer 308, which can act as a contact or cladding to the top of the semiconductor structure 216 nanopyramid. The adhesion layer 308 may be made using nickel, to act as a conductor. As with the other layers of arrangement 200, the actual composition and materials of the adhesion layer 308 may vary depending upon the specifics of a given embodiment and/or the type of semiconductor structure 216 being fabricated.

Next, where the semiconductor structure 216 is a micro-LED a mirror layer 306, which may be comprised of an Al—Si material, is deposited or otherwise formed over the semiconductor structure 216, such as using sputtering. The mirror's function is to reflect the visible light emitted from the micro-LED when the micro-LED is transferred to a display backplane. In the case of micro-LEDs, the mirror layer 306 is critical to achieving low power displays promised by the micro-LED technology. It should be understood that mirror layer 306 may be omitted in implementations where a different sort of semiconductor structure 216, other than an LED, is being fabricated. Similarly, the material used for the mirror layer 306 may vary depending upon the nature of the micro-LED, e.g. wavelength, output, etc., to a material most suitable to the given micro-LED implementation.

Finally, a contact layer 304, here comprised of a copper pad, may be fabricated or formed on top of the mirror layer 306 to serve as the anode electrode when the micro-LED is transferred to the display backplane. When the contact layer 304 is implemented as a copper pad, the copper pad may be used to bond to another copper pad on the display backplane. As with the other layers, contact layer 304 may be fabricated out of a different material depending upon the specifics of a particular semiconductor structure 216 that is being fabricated, or may be omitted entirely in some implementations. Furthermore, contact layer 304 may be selected or otherwise adapted to serve to allow the recipient substrate 302 to be attached to the arrangement 200 of layers. Once the contact layer 304 is formed, a recipient substrate 302 may be formed, bonded, or otherwise attached to the contact layer 304, resulting in a sort of sandwich of layers and the semiconductor structure 216 between the donor substrate 202 and the recipient substrate 302.

While the layers 304, 306, 308, and 310 are described above as being formed upon the semiconductor structure 216 while attached to the donor substrate 202, in some embodiments it may be possible to form one or more of these layers upon the recipient substrate 302 prior to adhering to the semiconductor structure 216. Such a process may depend upon the size and geometry of the semiconductor structure 216.

Following assembly of the arrangement 200 of layers and the additional layers depicted in FIG. 3, a laser may be directed to the ablation layer 206, such as through the substrate 202 and nucleation layer 204, to cause the ablation layer 206 to vaporize, thereby creating a pressure that forces the remaining layer of arrangement 200 to separate from the donor substrate 202 and nucleation layer 204, allowing the substrate 202 and nucleation layer 204 to be removed. This is illustrated in FIG. 3 by gap 312, remaining following ablation of the ablation layer 206. As can be seen, the ablation layer 206 is now missing, leaving the dielectric layers 208 and 210, plus oxide layer 310, adhesion layer 308, mirror layer 306, and contact layer 304 adhered to the recipient substrate 302 with the formed semiconductor structure 216.

In some embodiments where the semiconductor structure 216 is a micro-LED being manufactured into a display, the recipient substrate 302 (with processing described above) will be aligned and mated with a glass backplane. In other embodiments, the recipient substrate 302 may comprise part of all of the glass backplane. The donor substrate 202 may be irradiated from the backside with a pulsed laser to ablate the ablation layer 206 and promote liftoff/separation between the micro-LED structure and the nucleation layer 204. The display can then be completed by adding additional organic films, transparent conducting oxides and glass panels, similar to traditional displays. Where other types of devices are being manufactured, different backplanes may be utilized or omitted, with different processing steps carried out following ablative separation of the donor substrate 202 from the semiconductor structure 216, as appropriate to a given implementation.

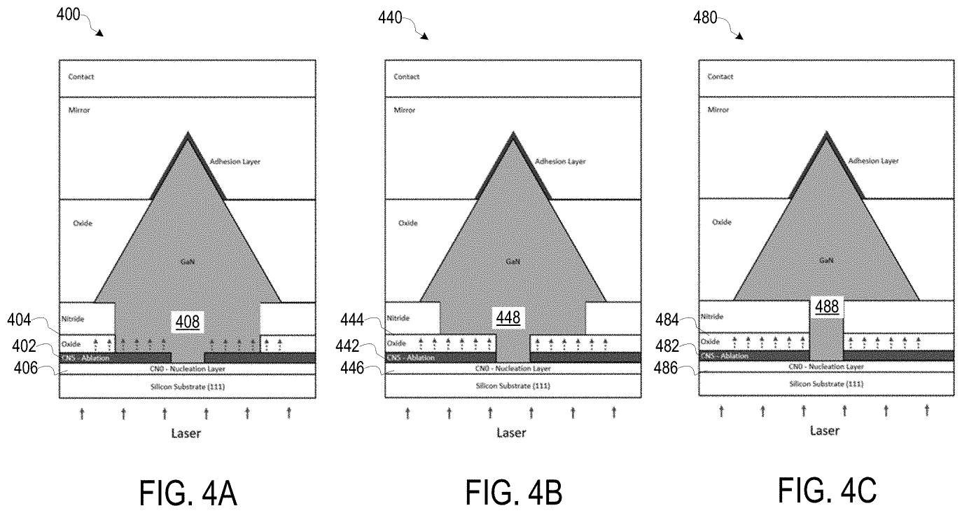

FIGS. 4A, 4B, and 4C illustrate several possible embodiments of the foregoing process. There are several design parameters reflected in the depicted embodiments to tune in order to maximize the ablation yield efficiency. First, the opening of the ablation layer 206 through to the nucleation layer 204 should be minimized, to the extent possible while still allowing proper growth of the semiconductor structure 216 with whatever growth process is selected. Minimizing this opening serves three purposes: 1) it reduces/minimizes the contact area between the material of the semiconductor structure 216 and the nucleation layer 204, thereby reducing the strong binding forces holding these materials together; 2) it maximizes the area of the semiconductor structure 216 that can be used for ablation/liftoff, as greater sacrificial ablation material will have more separation force; and 3) it positions the ablation layer directly below, rather than beside, the stem of the semiconductor structure 216, providing ablation liftoff force directly against the stem of the semiconductor structure 216. The increased coverage of the ablation layer 206 should be balanced with the need for sufficient contact between the semiconductor structure 216 and the nucleation layer 204 to properly execute the selected epitaxial growth process.

In the layer arrangement 400 of FIG. 4A, the aperture of the ablation layer 402 is relatively small compared to the opening of the dielectric layers 404, resulting in a small stem that contacts the nucleation layer 406. Ablation of the ablation layer 402 thus directly applies force to the underside of the semiconductor structure stem 408.

In the layer arrangement 440 of FIG. 4B, the aperture of the ablation layer 442 and the lower oxide layer of the dielectric layers 444 are approximately the same size, with the aperture of the upper nitride layer of the dielectric layers 444 being larger. Ablation of the ablation layer 442 thus applies force to the underside of the semiconductor structure stem 448 through the lower oxide layer.

In the layer arrangement 480 of FIG. 4C, the aperture of the ablation layer 482 and both the dielectric layers 484 are of the same size, with the pyramid top of the semiconductor structure extending a relatively large distance away from a narrow semiconductor structure stem 488. Ablation of the ablation layer 482 thus applies force to the underside of the pyramid top of the semiconductor structure, rather than to the stem 488.

In each of the example embodiment arrangements 400, 440, and 480, ablation of the respective ablation layer may result in side forces being exerted against the semiconductor structure stem, which may further aid in separate due to the relatively narrow width of the stem.

FIG. 5 is a flowchart of the operation of an example method 500 for creating a semiconductor structure, such as a semiconductor structure 216, and separating the structure from a donor substrate, such as a donor substrate 202, using ablation as part of a direct transfer method to a recipient substrate, such as recipient substrate 302, according to a possible embodiment. The operations of method 500 may be carried out in whole or in part, and in order or out of order as the operations may permit. Additional operations may be added in some embodiments, and some operation may be omitted in some embodiments. For specifics of some of these operations, the reader is referred to the description above in connection with FIGS. 2A, 2B, and 3.

In operation 502, a nucleation layer is formed atop a donor substrate. As discussed above, the nature of the nucleation layer may depend upon the type of semiconductor structure being formed, as well as the type of the donor substrate. In some embodiments, the donor substrate may act as the nucleation layer.

In operation 504, a suitable ablation layer is disposed upon the nucleation layer. The selection of the ablation layer material may be made with respect to the type of laser source that will be used for ablation, the type of material being used to grow the semiconductor structure, the geometry of the semiconductor structure and other layers disposed upon the donor substrate, and/or the desired force to be obtained from the ablation process. In forming the ablation layer, an aperture is formed that exposes the nucleation layer to allow epitaxial formation of the semiconductor structure. The ablation layer thus may be formed as a mask, with the aperture size selected to the minimum size required to ensure correct growth and formation of the semiconductor structure.

In operation 506, one or more dielectric layers may be formed upon the ablation layer. Each of the dielectric layers has an aperture that is roughly concentric with the aperture of the ablation layer, and are sized and shaped to guide the formation process of the semiconductor structure. The size of the apertures may be identical to, or larger than the aperture of the ablation layer and/or the aperture size of any layers that may be between the ablation layer and a given layer. Apertures that are larger than the ablation layer aperture may allow a greater direct force to be applied to the semiconductor structure during the ablation process.

In operation 508, the semiconductor structure is formed upon the nucleation layer, and grown through the apertures, to expand and cover a portion of the top dielectric layer in excess of the apertures. The process used to grow the semiconductor structure is typically some type of epitaxy, although other types of devices or applications may use a different type of growth process. The larger the amount of the semiconductor structure that expands laterally past the ablation layer aperture, the greater the amount of force the ablation process will exert when the semiconductor structure is to be removed from the donor substrate.

In operation 510, a recipient substrate is attached to the semiconductor structure. As discussed above with respect to FIG. 3, one or more additional layers may be deposited around the semiconductor structure and/or onto the recipient substrate prior to adhering to the semiconductor structure.

Finally, in operation 512, a laser is directed through to the ablation layer and pulsed with an appropriate time and energy to cause the ablation layer to vaporize, thereby releasing the donor substrate and nucleation layer from the semiconductor structure. The semiconductor structure is thus attached to the recipient substrate, and ready for any further processing that may be needed.

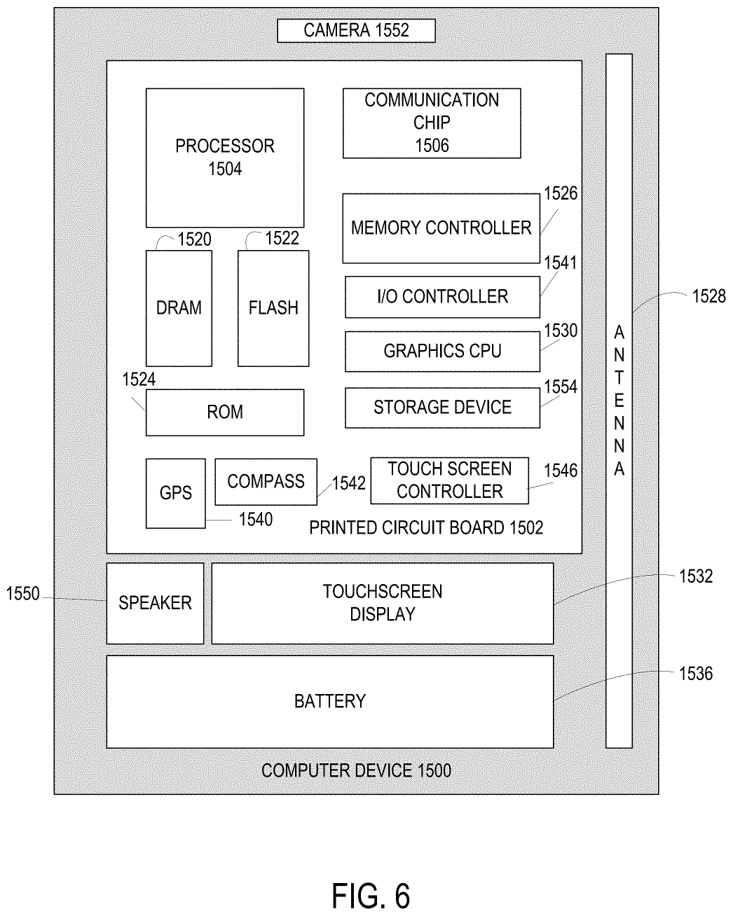

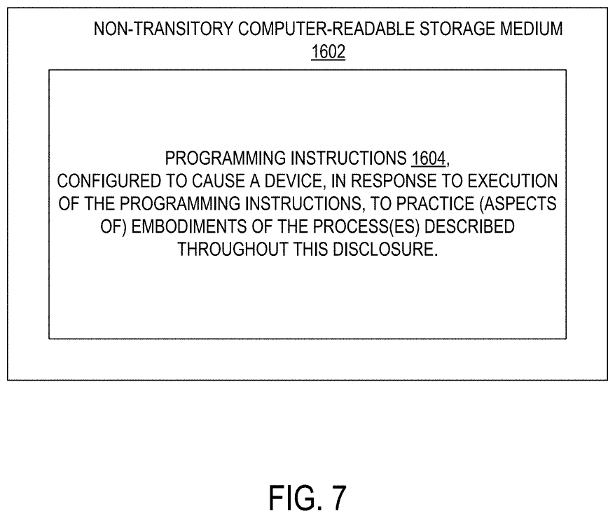

Method 500 may be carried out by an automated process or system, which may be performed by one or more computer devices 1500, discussed below with respect to FIG. 6, that may be running computer readable software, discussed below with respect to FIG. 7. Furthermore, it should be understood that while the foregoing discusses a semiconductor structure in singular, the foregoing processes may be used on a wafer in the simultaneous fabrication of multiple semiconductors, depending upon the particulars of a given implementation.

FIG. 6 illustrates an example computer device 1500 that may be employed by the apparatuses and/or methods described herein, in accordance with various embodiments. As shown, computer device 1500 may include a number of components, such as one or more processor(s) 1504 (one shown) and at least one communication chip 1506. In various embodiments, one or more processor(s) 1504 each may include one or more processor cores. In various embodiments, the one or more processor(s) 1504 may include hardware accelerators to complement the one or more processor cores. In various embodiments, the at least one communication chip 1506 may be physically and electrically coupled to the one or more processor(s) 1504. In further implementations, the communication chip 1506 may be part of the one or more processor(s) 1504. In various embodiments, computer device 1500 may include printed circuit board (PCB) 1502. For these embodiments, the one or more processor(s) 1504 and communication chip 1506 may be disposed thereon. In alternate embodiments, the various components may be coupled without the employment of PCB 1502.

Depending on its applications, computer device 1500 may include other components that may be physically and electrically coupled to the PCB 1502. These other components may include, but are not limited to, memory controller 1526, volatile memory (e.g., dynamic random access memory (DRAM) 1520), non-volatile memory such as read only memory (ROM) 1524, flash memory 1522, storage device 1554 (e.g., a hard-disk drive (HDD)), an I/O controller 1541, a digital signal processor (not shown), a crypto processor (not shown), a graphics processor 1530, one or more antennae 1528, a display, a touch screen display 1532, a touch screen controller 1546, a battery 1536, an audio codec (not shown), a video codec (not shown), a global positioning system (GPS) device 1540, a compass 1542, an accelerometer (not shown), a gyroscope (not shown), a speaker 1550, a camera 1552, and a mass storage device (such as hard disk drive, a solid state drive, compact disk (CD), digital versatile disk (DVD)) (not shown), and so forth.

In some embodiments, the one or more processor(s) 1504, flash memory 1522, and/or storage device 1554 may include associated firmware (not shown) storing programming instructions configured to enable computer device 1500, in response to execution of the programming instructions by one or more processor(s) 1504, to practice all or selected aspects of the method 500 or the various process flows described herein. In various embodiments, these aspects may additionally or alternatively be implemented using hardware separate from the one or more processor(s) 1504, flash memory 1522, or storage device 1554.

The communication chips 1506 may enable wired and/or wireless communications for the transfer of data to and from the computer device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to IEEE 802.20, Long Term Evolution (LTE), LTE Advanced (LTE-A), General Packet Radio Service (GPRS), Evolution Data Optimized (Ev-DO), Evolved High Speed Packet Access (HSPA+), Evolved High Speed Downlink Packet Access (HSDPA+), Evolved High Speed Uplink Packet Access (HSUPA+), Global System for Mobile Communications (GSM), Enhanced Data rates for GSM Evolution (EDGE), Code Division Multiple Access (CDMA), Time Division Multiple Access (TDMA), Digital Enhanced Cordless Telecommunications (DECT), Worldwide Interoperability for Microwave Access (WiMAX), Bluetooth, derivatives thereof, as well as any other wireless protocols that are designated as 3G, 4G, 5G, and beyond. The computer device 1500 may include a plurality of communication chips 1506. For instance, a first communication chip 1506 may be dedicated to shorter range wireless communications such as Wi-Fi and Bluetooth, and a second communication chip 1506 may be dedicated to longer range wireless communications such as GPS, EDGE, GPRS, CDMA, WiMAX, LTE, Ev-DO, and others.

In various implementations, the computer device 1500 may be a laptop, a netbook, a notebook, an ultrabook, a smartphone, a computer tablet, a personal digital assistant (PDA), a desktop computer, smart glasses, or a server. In further implementations, the computer device 1500 may be any other electronic device that processes data.

As will be appreciated by one skilled in the art, the present disclosure may be embodied as methods or computer program products. Accordingly, the present disclosure, in addition to being embodied in hardware as earlier described, may take the form of an entirely software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium. FIG. 7 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 1602 may include a number of programming instructions 1604. Programming instructions 1604 may be configured to enable a device, e.g., computer 1500, in response to execution of the programming instructions, to implement (aspects of) the method 500 or the various process flows described above. In alternate embodiments, programming instructions 1604 may be disposed on multiple computer-readable non-transitory storage media 1602 instead. In still other embodiments, programming instructions 1604 may be disposed on computer-readable transitory storage media 1602, such as, signals.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including but not limited to wireless, wireline, optical fiber cable, RF, etc.

Computer program code for carrying out operations of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

### EXAMPLES

The following examples pertain to further embodiments:

Example 1 is an apparatus, comprising a nucleation layer; an ablation layer formed on the nucleation layer, the ablation layer comprising a plurality of apertures that expose the nucleation layer; one or more dielectric layers formed on the ablation layer, the one or more dielectric layers comprising a plurality of apertures wherein individual of the dielectric layer apertures are disposed concentrically with individual of the ablation layer apertures and are at least as large as the individual ablation layer apertures; and a plurality of micro-light emitting diodes (micro-LEDs), each of the micro-LEDs comprising a stem and a body, wherein the stem of individual micro-LEDs is formed through the individual ablation layer apertures and individual dielectric layer apertures, and the body extends past the dielectric layer of the one or more dielectric layers that is most proximate to the body.

Example 2 includes the subject matter of example 1, or some other example herein, further comprising a substrate, and wherein the nucleation layer is formed on the substrate.

Example 3 includes the subject matter of example 1 or 2, or some other example herein, wherein the nucleation layer is comprised of Gallium and Nitrogen.

Example 4 includes the subject matter of any of examples 1-3, or some other example herein, wherein the ablation layer is comprised of a metal and Nitrogen.

Example 5 includes the subject matter of any of examples 1-4, or some other example herein, wherein the one or more dielectric layers are comprised of a compound that comprises Silicon, and Nitrogen or Oxygen.

Example 6 includes the subject matter of any of examples 1-5, or some other example herein, further comprising an adhesion layer formed on the micro-LED; a mirror layer formed on the adhesion layer; and a contact layer formed on the mirror layer.

Example 7 includes the subject matter of example 6, further comprising a recipient substrate adhered to the contact layer.

Example 8 includes the subject matter of any of examples 1-7, or some other example herein, wherein the micro-LED is formed from a compound that comprises Gallium and Nitrogen.

Example 9 includes the subject matter of any of examples 1-8, or some other example herein, wherein the bodies of the individual micro-LEDs comprise nano-pyramids.

Example 10 includes the subject matter of any of examples 1-9, or some other example herein, wherein the apertures of the one or more dielectric layers are larger than the apertures of the ablation layer.

Example 11 includes the subject matter of any of examples 1-10, or some other example herein, wherein the apertures of the dielectric layer that is most proximate to the ablation layer are the same size as the apertures of the ablation layer, and the apertures of the dielectric layer that is most proximate to the body are larger than the apertures of the ablation layer.

Example 12 includes the subject matter of any of examples 1-11, or some other example herein, wherein the apertures of the one or more dielectric layers are the same size as the apertures of the ablation layer, and wherein the apertures of the ablation layer are sized to a minimum size necessary for formation of the micro-LED.

Example 13 is a method, comprising forming, upon a substrate, a nucleation layer; forming, upon the nucleation layer, an ablation layer, the ablation layer having an aperture that partially exposes the nucleation layer; forming, upon the ablation layer, one or more dielectric layers including a top dielectric layer, individual one or more dielectric layers having an aperture that exposes the ablation layer aperture and that is least as large as the ablation layer aperture; and forming a micro-light emitting diode (micro-LED) from the nucleation layer that comprises a stem that fills the ablation layer aperture, the dielectric layer apertures, and a body that extends past the aperture of the dielectric layer most proximate to the body.

Example 14 includes the subject matter of example 13, or some other example herein, wherein the substrate is a donor substrate, and further comprising forming, on the micro-LED, a mirror layer; forming, on the mirror layer, a contact layer; and adhering, to the contact layer, a recipient substrate.

Example 15 includes the subject matter of example 13 or 14, or some other example herein, further comprising releasing the micro-LED from the nucleation layer by applying a laser pulse to the ablation layer sufficient to cause the ablation layer to ablate.

Example 16 includes the subject matter of example 14 or 15, or some other example herein, wherein at least a portion of the body of the micro-LED extends into the mirror layer.

Example 17 includes the subject matter of any of examples 14-16, or some other example herein, wherein the recipient substrate is a glass backplane.

Example 18 includes the subject matter of any of examples 14-17, or some other example herein, wherein the recipient substrate is a Silicon wafer.

Example 19 is a system, comprising a micro-light emitting diode (micro-LED) comprised of a stem and a body; a plurality of dielectric layers formed around the stem, such that the stem defines an aperture in individuals of the plurality of dielectric layers; at least one oxide layer formed around the body; a mirror layer formed on the at least one oxide layer, wherein the body at least partially extends into the mirror layer; a contact layer formed on the mirror layer; and a substrate adhered to the contact layer.

Example 20 includes the subject matter of example 19, or some other example herein, wherein the aperture of the dielectric layer most distal from the body is smaller than the aperture of the dielectric layer most proximate to the body.

Example 21 includes the subject matter of example 19, or some other example herein, wherein the apertures of the plurality of dielectric layers are of the same size, and are sized to a smallest size necessary for formation of the micro-LED.

Example 22 includes the subject matter of any of examples 19-21, wherein the plurality of dielectric layers comprises a layer comprising Oxygen and a layer comprising Nitrogen.

Example 23 includes the subject matter of any of examples 19-22, or some other example herein, wherein the system is a display.

Example 24 includes the subject matter of any of examples 19-23, or some other example herein, wherein the system is an optical interconnect.

What is claimed is:

1. An apparatus, comprising:
a nucleation layer;
an ablation layer formed on the nucleation layer, the ablation layer comprising a plurality of apertures that expose the nucleation layer;
one or more dielectric layers formed on the ablation layer, the one or more dielectric layers comprising a plurality of apertures wherein individual of the dielectric layer apertures are disposed concentrically with individual of the ablation layer apertures and are at least as large as the individual ablation layer apertures; and
a plurality of micro-light emitting diodes (micro-LEDs), each of the micro-LEDs comprising a stem and a body, wherein the stem of individual micro-LEDs is formed through the individual ablation layer apertures and individual dielectric layer apertures, and the body extends past the dielectric layer of the one or more dielectric layers that is most proximate to the body.

2. The apparatus of claim 1, further comprising a substrate, and wherein the nucleation layer is formed on the substrate.

3. The apparatus of claim 2, wherein the nucleation layer is comprised of Gallium and Nitrogen.

4. The apparatus of claim 1, wherein the ablation layer is comprised of a metal and Nitrogen.

5. The apparatus of claim 1, wherein the one or more dielectric layers are comprised of a compound that comprises Silicon, and Nitrogen or Oxygen.

6. The apparatus of claim 1, further comprising:
an adhesion layer formed on the micro-LED;
a mirror layer formed on the adhesion layer; and
a contact layer formed on the mirror layer.

7. The apparatus of claim 6, further comprising a recipient substrate adhered to the contact layer.

8. The apparatus of claim 1, wherein the micro-LED is formed from a compound that comprises Gallium and Nitrogen.

9. The apparatus of claim 1, wherein the bodies of the individual micro-LEDs comprise nano-pyramids.

10. The apparatus of claim 1, wherein the apertures of the one or more dielectric layers are larger than the apertures of the ablation layer.

11. The apparatus of claim 1, wherein the apertures of the dielectric layer that is most proximate to the ablation layer are the same size as the apertures of the ablation layer, and the apertures of the dielectric layer that is most proximate to the body are larger than the apertures of the ablation layer.

12. The apparatus of claim 1, wherein the apertures of the one or more dielectric layers are the same size as the apertures of the ablation layer, and wherein the apertures of the ablation layer are sized to a minimum size necessary for formation of the micro-LED.

13. A method, comprising:
forming, upon a substrate, a nucleation layer;
forming, upon the nucleation layer, an ablation layer, the ablation layer having an aperture that partially exposes the nucleation layer;
forming, upon the ablation layer, one or more dielectric layers including a top dielectric layer, individual one or more dielectric layers having an aperture that exposes the ablation layer aperture and that is least as large as the ablation layer aperture; and
forming a micro-light emitting diode (micro-LED) from the nucleation layer that comprises a stem that fills the ablation layer aperture, the dielectric layer apertures, and a body that extends past the aperture of the dielectric layer most proximate to the body.

14. The method of claim 13, wherein the substrate is a donor substrate, and further comprising:
forming, on the micro-LED, a mirror layer;
forming, on the mirror layer, a contact layer; and
adhering, to the contact layer, a recipient substrate.

15. The method of claim 14, further comprising releasing the micro-LED from the nucleation layer by applying a laser pulse to the ablation layer sufficient to cause the ablation layer to ablate.

16. The method of claim 14, wherein at least a portion of the body of the micro-LED extends into the mirror layer.

17. The method of claim 14, wherein the recipient substrate is a glass backplane.

18. The method of claim 14, wherein the recipient substrate is a Silicon wafer.

19. A system, comprising:
a micro-light emitting diode (micro-LED) comprised of a stem and a body;
a plurality of dielectric layers formed around the stem, such that the stem defines an aperture in individuals of the plurality of dielectric layers;
at least one oxide layer formed around the body;
a mirror layer formed on the at least one oxide layer, wherein the body at least partially extends into the mirror layer;
a contact layer formed on the mirror layer; and
a substrate adhered to the contact layer.

20. The system of claim 19, wherein the aperture of the dielectric layer most distal from the body is smaller than the aperture of the dielectric layer most proximate to the body.

21. The system of claim 19, wherein the apertures of the plurality of dielectric layers are of the same size, and are sized to a smallest size necessary for formation of the micro-LED.

22. The system of claim 19, wherein the plurality of dielectric layers comprises a layer comprising Oxygen and a layer comprising Nitrogen.

23. The system of claim 19, wherein the system is a display.

24. The system of claim 19, wherein the system is an optical interconnect.
